(19) United States
(12) Patent Application Publication
(10) Pub. No.: US 2018/0053753 A1
(43) Pub. Date: Feb. 22, 2018

(54) STACKABLE MOLDED PACKAGES AND METHODS OF MANUFACTURE THEREOF

(71) Applicant: FREESCALE SEMICONDUCTOR, INC., Austin, TX (US)

(72) Inventors: Akhilesh Kumar Singh, Austin, TX (US); Nishant Lakhera, Austin, TX (US); Navas Khan Oratti Kalandar, Austin, TX (US)

(21) Appl. No.: 15/237,827

(22) Filed: Aug. 16, 2016

(51) Int. Cl. H01L 25/10; H01L 25/00

(52) U.S. Cl. CPC H01L 25/105; H01L 25/50; H01L 2225/1082; H01L 2225/1041; H01L 2225/1058; H01L 2225/1023

(57) ABSTRACT

A stackable package assembly and method of manufacturing is provided. The method includes attaching a plurality of interconnect balls to a first surface of a substrate, and encapsulating the first surface of the substrate and the plurality of interconnect balls with an encapsulant. A trench is formed in a first surface of the encapsulant exposing a portion the interconnect balls. An interposer is provided having a first interconnect layer. An assembly is formed by attaching connection sites of a first interconnect layer to the exposed portion of the interconnect balls, the first surface of the second substrate extending into the trench.

### BACKGROUND

### Field

This disclosure relates generally to device packaging, and more specifically, to stackable molded packages and methods of making the same.

### Related Art

Packaged semiconductor devices are often found in a large spectrum of electronic products—from sewing machines to washing machines, from automobiles to cellular telephones, and so on. These packaged semiconductor devices are typically mounted on a substrate such as a printed circuit board. In order to keep product costs low or to reduce product costs, it is common to minimize the amount of material used within the product, frequently reducing the size of the product itself. As electronic products are reduced in size, printed circuit board real estate becomes more precious putting additional constraints on the size, number, and features of packaged semiconductor devices. Stackable packages may be stacked in package-on-package arrangement, maximizing functionality while having a minimal impact on printed circuit board real estate.

### BRIEF DESCRIPTION OF THE DRAWINGS

The present invention is illustrated by way of example and is not limited by the accompanying figures, in which like references indicate similar elements. Elements in the figures are illustrated for simplicity and clarity and have not necessarily been drawn to scale.

FIGS. 1-3 illustrate, in simplified cross-sectional views, stages of manufacture of an exemplary stackable package according to an embodiment of the present disclosure.

FIGS. 4-5 illustrate, in simplified plan and cross-sectional views, an exemplary interposer according to an embodiment of the present disclosure.

FIGS. 6-7 illustrate, in simplified cross-sectional views, an exemplary assembly formed with the interposer of FIG. 5 and the stackable package of FIG. 3 according to an embodiment of the present disclosure.

FIG. 8 illustrates, in a simplified cross-sectional view, an exemplary package-on-package configuration according to an embodiment of the present disclosure.

### DETAILED DESCRIPTION

Generally, there is provided, a stackable package and method of manufacturing that incorporates embedded interconnect balls allowing for flexible package-on-package configurations using a reconfigurable interposer. Formed trenches expose a top portion of the embedded interconnect balls providing for attachment of a variety of interposers. An assembly formed by attaching an interposer to the stackable package allows for a packaged device to be mounted over the stackable package.

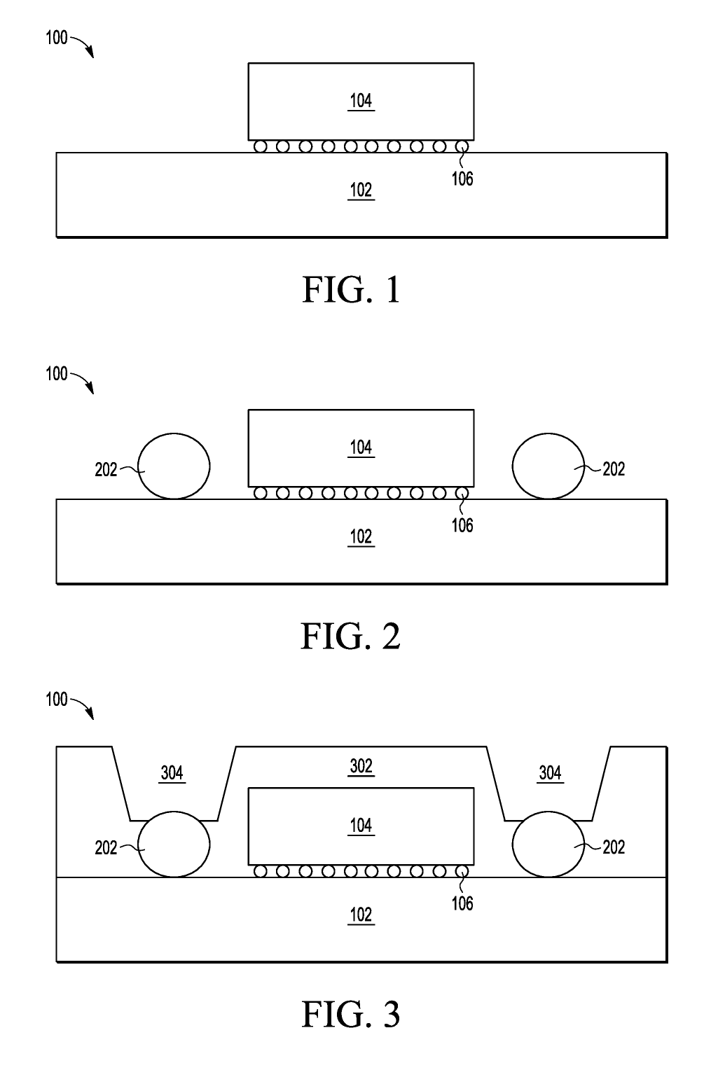

FIG. 1 illustrates, in a simplified cross-sectional view, a stage of manufacture of an exemplary stackable package 100, including a first substrate and a first die according to an embodiment of the present disclosure. The substrate 102 includes multiple interconnect or routing layers (not shown) which allows for signal communication from a top surface of substrate 102 to a bottom surface of substrate 102, for example. Die 104 is attached active surface face down to substrate 102 in a flip chip configuration by way of conductive bumps or bonding balls 106. Although FIG. 1 shows die 104 as being flip chip bonded to substrate 102, die 104 may be attached to substrate 102 using other techniques, such as with active surface up, having bond wire provide electrical connectivity between the active surface of the die 104 and the top surface of the substrate 102.

Substrate 102 may include any suitable non-conductive material such as ceramic, FR-4, BT-epoxy, or organic bulk materials (e.g., standard printed circuit board (PCB) materials). Substrate 102 may be formed as a laminate having conductive interconnect layers disposed between non-conductive layers, for example. Substrate 102 may be formed in any suitable shape, such as rectangles, and squares, for example. The interconnect layers can be attached to or formed in the substrate 102 through any suitable process such as sputtering, deposition, plating, and the like, for example. Multiple interconnect layers of substrate 102 allow for signal communication between a top side surface of substrate 102 and a bottom side surface of substrate 102. The interconnect layers can be formed from a variety of electrically conductive materials including, for example, copper, gold, silver, aluminum, nickel, tungsten, and alloys thereof to include solder, doped materials (e.g., phosphorus, boron-doped polysilicon), superconducting materials and ceramics (e.g., copper oxide materials, iron-based materials, and other metallic-based materials. The interconnect layers may also be formed of more than one type of material depending on the process to create the conductive layers, assembly and particular package structures.

The die 104 may be a semiconductor die formed of any semiconductive material, such as silicon, germanium, gallium arsenide, gallium nitride and the like. Die 104 may include any or combination of digital circuits, analog circuits, memory, processor, MEMS, sensors, and the like. In some embodiments, die 104 may include one or more discrete components such as resistor, inductor, capacitor, high-voltage field effect transistor, and the like for example. Die 104 may be formed in any size or geometry.

Conductive bonding balls 106 electrically couple bonding sites on die 104 with the interconnect layers of substrate 102. Bonding balls 106 may be referred to as solder balls or solder bumps in this embodiment. Bonding balls 106 may be formed of one or more conductive materials such as tin, silver, copper, and the like, for example. In alternative embodiments, bonding balls 106 may be any suitable conductive structure such as gold studs, copper pillars, and the like, to electrically couple bonding sites on die 104 with the interconnect layers of substrate 102, for example.

FIG. 2 illustrates, in a simplified cross-sectional view, a subsequent stage of manufacture of stackable package 100, including first interconnect balls 202 attached to substrate 102 according to an embodiment of the present disclosure. Interconnect balls 202 are electrically coupled to one or more interconnect layers of substrate 102. Interconnect balls 202 may be formed of one or more conductive materials such as tin, silver, copper, and the like, for example. In alternative embodiments, interconnect balls 202 may include any suitable conductive structure such as gold studs, copper pillars, and the like, for example.

FIG. 3 illustrates, in a simplified cross-sectional view, a subsequent stage of manufacture of stackable package 100, including encapsulant 302 according to an embodiment of the present disclosure. The top surface of substrate 102, die 104, and a portion of interconnect balls 202 are encapsulated mold compound material. The mold compound material can be any suitable encapsulant including, for example, silica-filled epoxy molding compounds, plastic encapsulation resins, and other polymeric materials such as silicones, polyimides, phenolics, and polyurethanes. The mold compound material can be applied by a variety of processing techniques used in encapsulation. For example, film-assisted molding can be used whereby a cavity, recess, or trench 304 is formed in the encapsulant leaving a top portion of the interconnect balls 202 not covered by molding material, thus exposing the top portion.

The trench 304 may be configured in a variety of shapes such as strips, L-shapes, C-shapes, rectangles, squares, other orthogonal and non-orthogonal shapes for example, depending upon package layout and configuration. Trench 304 is generally formed in a continuous shape or set of shapes and configured such that conductive surfaces of the exposed interconnect balls 202 can be mated with an interposer. In this embodiment, trench 304 is formed in a continuous rectangular or square shape surrounding die 104. In this embodiment, the exposed surface of interconnect balls 202 are recessed below the top surface of encapsulant 302 such that when mated with the interposer, a portion of the interposer extends downward into trench 304. In this embodiment, the height of the top surface of encapsulant 302, as measured from the top surface of substrate 102, may be at least twice the height of interconnect balls 202. In some embodiments, the height of the top surface of encapsulant 302, as measured from the top surface of substrate 102, may be at least 1.2 times the height of interconnect balls 202.

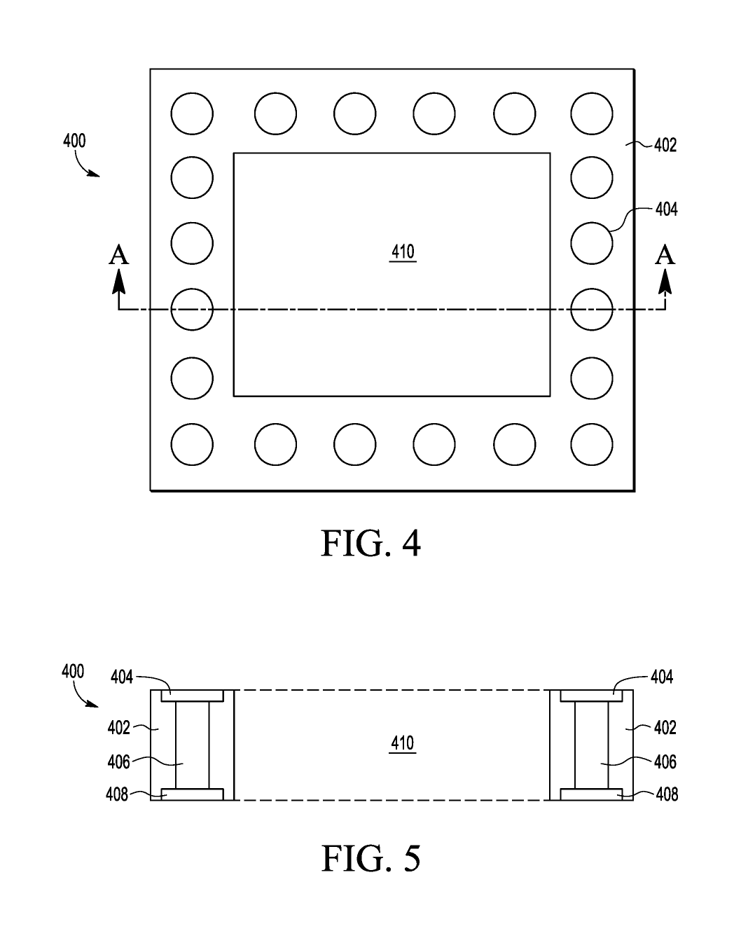

FIG. 4 illustrates, in a simplified plan view, an exemplary interposer 400 according to an embodiment of the present disclosure. Interposer 400 is shown top-side-up in a square shaped configuration with opening 410 in the inner portion of the square. Interposer 400 includes substrate 402 having interconnect formed from signal conduits and interconnect or routing layers. Connection sites of first interconnect layer 404 are distributed around the top side of substrate 402. A cross-sectional view of interposer 400 is taken at section line A-A. It should be understood that interposer 400 and stackable package 100 may each be formed or manufactured independently.

FIG. 5 illustrates, in a simplified cross-sectional view, the exemplary interposer of FIG. 4 according to an embodiment of the present disclosure. The cross-sectional view of FIG. 5 is taken at section line A-A of the exemplary interposer 400. The interposer 400 includes substrate 402 having multi-layer interconnect that includes signal conduits 406 and first and second interconnect or routing layers 404 and 408. The interposer 400 may include several interconnect layers. Connection sites of first interconnect layer 404 are distributed at a top surface of substrate 402 and connection sites of second interconnect layer 408 are distributed at a bottom surface of substrate 402. Connection sites or pads provide a location for electrical connectivity to interconnect layers of the interposer.

Substrate 402 may include any suitable multi-layer substrate, formed of non-conductive material such as ceramic or organic bulk materials (e.g., multi-layer laminate printed circuit board (PCB) materials). Substrate 402 may be configured in a variety of shapes such as strips, L-shapes, C-shapes, rectangles, squares, other orthogonal and non-orthogonal shapes for example, depending upon the stackable package 100 layout and configuration. It may be desirable for the configuration of substrate 402 to complement the trench 304 as configured in stackable package 100.

In general, substrate 402 is formed in a shape and configured such that connection sites of second interconnect layer 408 at the bottom surface of interposer 400 can be mated with conductive surfaces of the exposed interconnect balls 202 of stackable package 100. Connection sites of first interconnect layer 404 at the top surface of interposer 400 are arranged such that conductive surfaces of a packaged device can be electrically coupled to the interposer 400. By reconfiguring the arrangement of connection sites of first interconnect layer 404 at the top surface of interposer 400, a myriad of packaged devices can be coupled to the interposer 400.

Signal conduits 406 can be attached to or formed in the substrate 402 through any suitable process such as sputtering, deposition, and plating, for example. Signal conduits 406 allow for signal communication from a top surface of substrate 402 at first interconnect layer 404 to a bottom surface of substrate 402 at second interconnect layer 408, for example. Signal conduits 406 can be formed from a variety of electrically conductive materials including, for example, copper, gold, silver, aluminum, nickel, tungsten, and alloys thereof to include solder, doped materials (e.g., phosphorus, boron-doped polysilicon), superconducting materials and ceramics (e.g., copper oxide materials, iron-based materials, and other suitable metallic-based materials. Signal conduits 304 could also be formed of more than one type of material depending on the process to create the conduits, assembly and particular package structures.

Interconnect layers 404 and 408 may be formed of any suitable conductive material, such as copper, nickel, aluminum, and alloys thereof, for example. Connection sites of interconnect layer 408 allows for connecting conductive surfaces of the exposed interconnect balls 202 with interposer 400. Connection sites of interconnect layer 408 can provide for connecting interconnect balls, gold studs, copper pillars, and the like, for example.

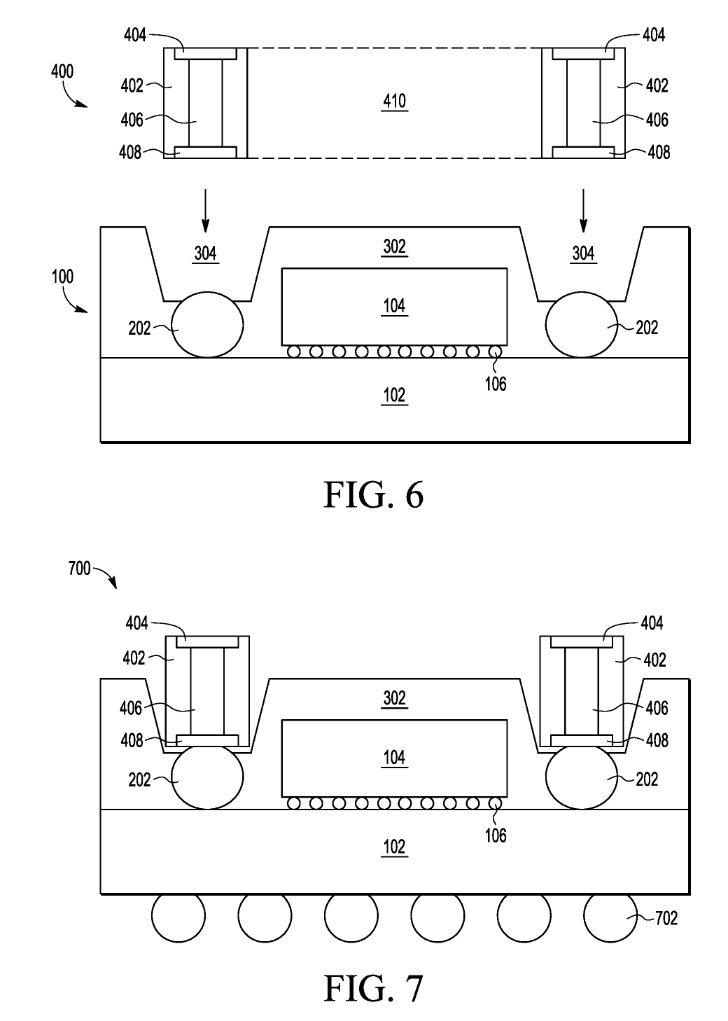

FIG. 6 illustrates, in a simplified cross-sectional view, interposer 400 positioned with stackable package 100 to form an exemplary assembly according to an embodiment of the present disclosure. Interposer is positioned such that connection sites on interconnect layer 408 are aligned with corresponding conductive surfaces of the exposed interconnect balls 202.

FIG. 7 illustrates, in a simplified cross-sectional view, exemplary assembly 700 formed with interposer 400 and stackable package 100 according to an embodiment of the present disclosure. Interposer 400 is attached to stackable package 100, having connection sites of interconnect layer 408 electrically coupled to conductive surfaces of exposed interconnect balls 202. Interposer 400 extends into the cavity formed on the top side of stackable package 100 when attached. Connection sites of interconnect layer 408 and conductive surfaces of exposed interconnect balls 202 can be affixed to one another using known techniques such as solder reflow and the like, for example.

Conductive ball connectors 702 are formed on a bottom surface of substrate 102 for connecting the stackable package 100 to other packages or other components, such as printed circuit boards. Ball connectors 702 electrically coupled to interconnect layers of substrate 102. In one embodiment, ball connectors 702 are solder balls. Ball connectors 702 may also be referred to as ball conductors, being formed of one or more conductive materials. Ball connectors 702 may be formed of similar materials as interconnect balls 202 shown in FIG. 2. In some embodiments, ball connectors 702 may be formed of materials different from interconnect balls 202. Known techniques may be used in the formation, placement, and attachment of ball connectors 702. In this embodiment, ball connectors 702 are formed on the bottom surface of substrate 102 after interposer 400 is attached to stackable package 100. In some embodiments, ball connectors 702 can be formed on the bottom surface of substrate 102 before interposer 400 is attached. In alternative embodiments, ball connectors 702 and interposer 400 can be concurrently attached to stackable package 100 during a same solder reflow step.

In the exemplary assembly 700 shown in FIG. 7, it can be realized that conductive pathways, including signal conduits 406, interconnect layers 404 and 408, along with interconnect balls 202 and ball connectors 702, are formed between connection sites of first interconnect layer 404 at the top surface of interposer 400 and ball connectors 702 for at the bottom surface of stackable package 300. Interconnect or routing layers (not shown) of substrate 102 provides conductive pathways between die 104 and ball connectors 702 and between die 104 and connection sites of first interconnect layer 404. These conductive pathways allow for signal communication from die 104 to a packaged device connected at connection sites of first interconnect layer 404, for example.

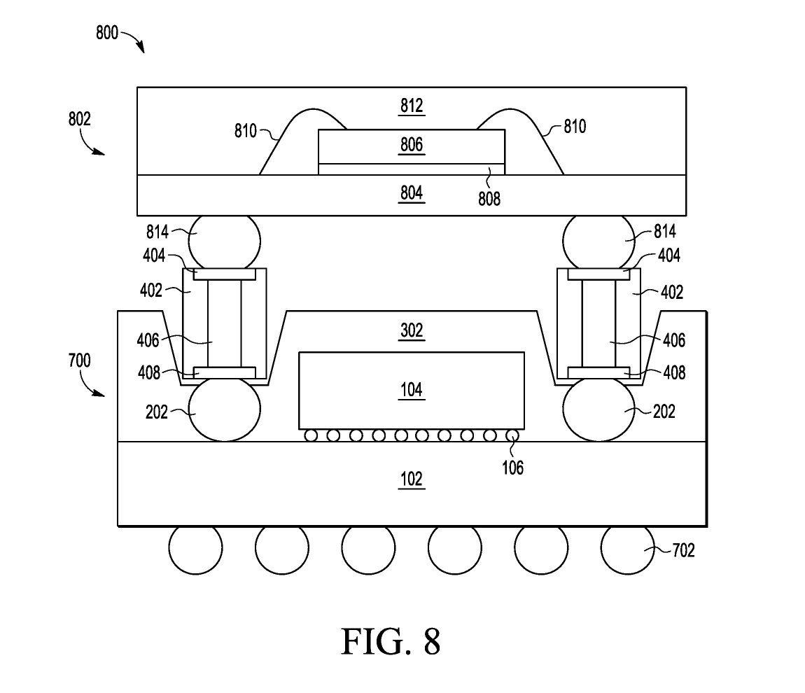

FIG. 8 illustrates, in a simplified cross-sectional view, an exemplary package-on-package (PoP) configuration 800 according to an embodiment of the present disclosure. PoP configuration 800 includes an exemplary packaged device 802 mounted to exemplary assembly 700.

Packaged device 802 may include any device and/or discrete components suitable for mounting in a PoP configuration. In this embodiment, exemplary packaged device 802 includes substrate 804, die 806, and encapsulant 812. Die 806 may include any or combination of digital circuits, analog circuits, memory, processor, MEMS, sensors, resistors, inductors, capacitors, discrete transistors, and the like for example. In this embodiment, die 806 is attached to substrate 804 by way of die attach material 808. Bond wires 810 electrically couple locations on an active surface of die 806 with locations at a top surface of substrate 804. Ball connectors 814 are formed at a bottom surface of substrate 804 and allow for signals to be electrically coupled to locations on the top side of substrate 804 by way of substrate interconnect (not shown). Ball connectors 814 are formed and placed using known techniques and materials. Ball connectors 814 are arranged in a configuration that matches one or more of the connection sites of interconnect layer 404 of assembly 700. The ball connectors 814 and the connection sites of interconnect layer 404 can be affixed to one another using known techniques and methods such as solder reflow and the like. Embodiments of the present disclosure are not limited to coupling a packaged device at the connection sites of interconnect layer 404. For example, discrete components, heat sinks, or shields can be solder coupled to the connection sites of interconnect layer 404.

In the exemplary package-on-package (PoP) configuration 800 of FIG. 8, it can be realized that signal conduits 406, interconnect layers 404 and 408, along with interconnect balls 202 and ball connectors 702 and 814, form conductive pathways, between packaged device 802 and assembly 700. These conductive pathways can be used, for example, to enable electrical connection between die 104 of stackable package 300 and die 806 of PoP mounted packaged device 802.

Generally, there is provided, a method of manufacturing a package assembly including attaching a plurality of interconnect balls to a first surface of a first substrate; encapsulating the first surface of the first substrate and the plurality of interconnect balls with an encapsulant; forming a trench in a first surface of the encapsulant exposing a portion the interconnect balls, exposed portion of the interconnect balls providing electrical connectivity to a first conductive layer disposed at the first surface of the first substrate; providing an interposer having a first interconnect layer disposed at a first surface of a second substrate; and forming an assembly by attaching connection sites of the first interconnect layer to exposed portion of the interconnect balls, the first surface of the second substrate extending into the trench. The method may further include attaching a first plurality of ball connectors to a second surface of the first substrate. Encapsulating may further include encapsulating a semiconductor die attached to the first surface of the first substrate. The semiconductor die may be attached to the first surface of the first substrate in a flip chip configuration. The trench may be a continuous trench at least partially surrounding the semiconductor die. Forming an assembly may further include a second surface of the second substrate located farther from the first surface of a first substrate than the first surface of the encapsulant. The method may further include attaching a packaged device to connection sites of a second interconnect layer disposed at the second surface of the second substrate. The packaged device may be over the semiconductor die. The trench may be formed using a film-assisted molding technique.

In another embodiment, there is provided, a method of manufacturing a package assembly including providing a package substrate having a first surface; attaching a die to the first surface of the package substrate; attaching a plurality of interconnect balls to the first surface of the package substrate, the plurality of interconnect balls at least partially surrounding the die and electrically connected to the die; encapsulating the first surface of the package substrate, die, and plurality of interconnect balls with an encapsulant; forming a cavity in a first surface of the encapsulant exposing a top portion the interconnect balls, the exposed top portion of the interconnect balls providing electrical connectivity to a first conductive layer disposed at the first surface of the package substrate; providing an interposer having a first interconnect layer disposed at a first surface of an interposer substrate; and forming an assembly by attaching connection sites of the first interconnect layer to exposed top portion of the interconnect balls, the first surface of the interposer substrate extending into the cavity. The method may further include attaching a first plurality of ball connectors to a second surface of the package substrate. The semiconductor die may be attached to the first surface of the package substrate in a flip chip configuration. Forming a cavity may be forming a continuous cavity exposing a top portion the interconnect balls at least partially surrounding the die. Forming an assembly may further include a second surface of the interposer substrate extending above the first surface of the encapsulant. The method may further include attaching a packaged device to connection sites of a second interconnect layer disposed at the second surface of the interposer substrate. The plurality of interconnect balls may be attached to the first surface of the package substrate using a solder reflow process.

In yet another embodiment, there is provided, a package assembly including a first package including: a package substrate having a first surface, a die attached to the first surface of the package substrate, a plurality of interconnect balls attached to the first surface of the package substrate, the plurality of interconnect balls at least partially surrounding the die, an encapsulant having a top surface, the encapsulant encapsulating the first surface of the package substrate, die, and plurality of interconnect balls, and a trench formed in the top surface of the encapsulant exposing a top portion the interconnect balls, the exposed top portion of the interconnect balls; and an interposer including: an interposer substrate having a top surface and a bottom surface, the bottom surface positioned in the trench and below the top surface of the encapsulant, a first interconnect layer disposed at the top surface of the interposer substrate, and a second interconnect layer disposed at the bottom surface of the interposer substrate, the second interconnect layer having connection sites coupled to the exposed top portion of the interconnect balls. The package assembly may further include a first plurality of ball connectors attached to a second surface of the package substrate. The package assembly may further include a second package attached to connection sites of the first interconnect layer. The die may be attached to the first surface of the package substrate in a flip chip configuration.

By now it should be appreciated that a stackable package and method of manufacturing have been provided which incorporates embedded interconnect balls allowing for flexible package-on-package configurations using a reconfigurable interposer. Formed trenches expose a top portion of the embedded interconnect balls providing for attachment of a variety of interposers. An assembly formed by attaching an interposer to the stackable package allows for a packaged device to be mounted over the stackable package.

The terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

Although the invention is described herein with reference to specific embodiments, various modifications and changes can be made without departing from the scope of the present invention as set forth in the claims below. Accordingly, the specification and figures are to be regarded in an illustrative rather than a restrictive sense, and all such modifications are intended to be included within the scope of the present invention. Any benefits, advantages, or solutions to problems that are described herein with regard to specific embodiments are not intended to be construed as a critical, required, or essential feature or element of any or all the claims.

The term “coupled,” as used herein, is not intended to be limited to a direct coupling or a mechanical coupling.

Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles.

Unless stated otherwise, terms such as “first” and “second” are used to arbitrarily distinguish between the elements such terms describe. Thus, these terms are not necessarily intended to indicate temporal or other prioritization of such elements.

1. A method of manufacturing a package assembly, the method comprising:
attaching a plurality of interconnect balls to a first surface of a first substrate;
encapsulating the first surface of the first substrate and the plurality of interconnect balls with an encapsulant;
forming a trench in a first surface of the encapsulant exposing a portion the interconnect balls using a film-assisted molding technique, the exposed portion of the interconnect balls extending out of the encapsulant and providing electrical connectivity to a first conductive layer disposed at the first surface of the first substrate;
providing an interposer having a first interconnect layer disposed at a first surface of a second substrate; and
forming an assembly by attaching connection sites of the first interconnect layer to exposed portion of the interconnect balls, the first surface of the second substrate extending into the trench.

2. The method of claim 1, further comprising attaching a first plurality of ball connectors to a second surface of the first substrate.

3. The method of claim 1, wherein encapsulating further includes encapsulating a semiconductor die attached to the first surface of the first substrate.

4. The method of claim 3, wherein the semiconductor die is attached to the first surface of the first substrate in a flip chip configuration.

5. The method of claim 3, wherein the trench is a continuous trench at least partially surrounding the semiconductor die.

6. The method of claim 3, wherein forming the assembly further includes a second surface of the second substrate located farther from the first surface of a first substrate than the first surface of the encapsulant.

7. The method of claim 6, further comprising attaching a packaged device to connection sites of a second interconnect layer disposed at the second surface of the second substrate.

8. The method of claim 7, wherein the packaged device is over the semiconductor die.

9. (canceled)

10. A method of manufacturing a package assembly, the method comprising:
providing a package substrate having a first surface;
attaching a die to the first surface of the package substrate;
attaching a plurality of interconnect balls to the first surface of the package substrate, the plurality of interconnect balls at least partially surrounding the die and electrically connected to the die;
encapsulating the first surface of the package substrate, die, and plurality of interconnect balls with an encapsulant;
forming a cavity in a first surface of the encapsulant exposing a top portion the interconnect balls using a film-assisted molding technique, the exposed top portion of the interconnect balls extending out of the encapsulant and providing electrical connectivity to a first conductive layer disposed at the first surface of the package substrate;
providing an interposer having a first interconnect layer disposed at a first surface of an interposer substrate; and
forming an assembly by attaching connection sites of the first interconnect layer to exposed top portion of the interconnect balls, the first surface of the interposer substrate extending into the cavity.

11. The method of claim 10, further comprising attaching a first plurality of ball connectors to a second surface of the package substrate.

12. The method of claim 10, wherein the semiconductor die is attached to the first surface of the package substrate in a flip chip configuration.

13. The method of claim 10, wherein forming the cavity is forming a continuous cavity exposing a top portion the interconnect balls at least partially surrounding the die.

14. The method of claim 10, wherein forming the assembly further includes a second surface of the interposer substrate extending above the first surface of the encapsulant.

15. The method of claim 10, further comprising attaching a packaged device to connection sites of a second interconnect layer disposed at the second surface of the interposer substrate.

16. The method of claim 10, wherein the plurality of interconnect balls is attached to the first surface of the package substrate using a solder reflow process.

17. A package assembly comprising:
a first package including:
a package substrate having a first surface,
a die attached to the first surface of the package substrate,
a plurality of interconnect balls attached to the first surface of the package substrate, the plurality of interconnect balls at least partially surrounding the die,
an encapsulant having a top surface, the encapsulant encapsulating the first surface of the package substrate, die, and plurality of interconnect balls, and
a trench formed in the top surface of the encapsulant exposing a top portion the interconnect balls, the exposed top portion of the interconnect balls extending out of the encapsulant;
an interposer including:
an interposer substrate having a top surface and a bottom surface, the bottom surface positioned in the trench and below the top surface of the encapsulant,
a first interconnect layer disposed at the top surface of the interposer substrate, and
a second interconnect layer disposed at the bottom surface of the interposer substrate, the second interconnect layer having connection sites coupled to the exposed top portion of the interconnect balls; and
a second package attached to connection sites of the first interconnect layer.

18. The package assembly of claim 17, further comprising a first plurality of ball connectors attached to a second surface of the package substrate.

19. (canceled)

20. The package assembly of claim 17, wherein the die is attached to the first surface of the package substrate in a flip chip configuration.

21. The package assembly of claim 17, wherein the trench is formed as a continuous rectangle or square shape surrounding the die and is set inward of an edge of the package substrate.

22. The package assembly of claim 17, further comprising a second plurality of interconnect balls disposed between the second package and the connection sites of the first interconnect layer.
